(19) United States
(12) Patent Application Publication
(10) Pub. No.: US 2015/0192440 A1
(43) Pub. Date: Jul. 9, 2015

(54) Systems and Methods for Initiating Calibration of a Sensor

(71) Applicant: InvenSense, Incorporated, San Jose, CA (US)

(72) Inventors: Rosa M.Y. Chow, Redwood City, CA (US); William Kerry Keal, Santa Clara, CA (US); James B. Lim, Saratoga, CA (US)

(73) Assignee: InvenSense, Incorporated, San Jose, CA (US)

(21) Appl. No.: 14/149,707

(22) Filed: Jan. 7, 2014

(51) Int. Cl. G01D 18/00; G01R 33/00; G01L 27/00; G01P 21/00; G01C 25/00

(52) U.S. Cl. CPC G01D 18/00; G01P 21/00; G01C 25/005; G01L 27/005; G01R 33/0035

(57) ABSTRACT

A device having a sensor may be calibrated by obtaining a condition of a device incorporating the sensor and initiating a calibration operation for the sensor based, at least in part, on the condition of the device. The condition may be a motion state, a charging state, a pattern of motion, an orientation, a location, a surrounding environment measurement, sensor usage, an age of calibration, a quality of calibration, or any combination. Further, the sensor may be an accelerometer, a gyroscope, a magnetometer or a pressure sensor.

### FIELD OF THE PRESENT DISCLOSURE

This disclosure generally relates to the calibration of sensors and more specifically to initiating the calibration of a sensor at one or more advantageous times.

### BACKGROUND

The development of microelectromechanical systems (MEMS) has enabled the incorporation of a wide variety of sensors into mobile devices, such as cell phones, laptops, tablets, gaming devices and other portable, electronic devices. Non-limiting examples of such sensors include an accelerometer, a gyroscope, a magnetometer, a pressure sensor, a microphone, a proximity sensor, an ambient light sensor, an infrared sensor, and the like. Further, sensor fusion processing may be performed to combine the data from a plurality of sensors to provide an improved characterization of the device's motion or orientation. However, due to the nature of electronics and mechanics, MEMS-based sensors may be prone to having bias (offset) and sensitivity errors. These errors may drift and or change due to temperature, humidity, time, assembly stress and other changes in peripheral conditions. In turn, inaccurate bias may result in decreased quality of sensor data and may complicate the sensor fusion process used to estimate parameters such as attitude (e.g., pitch, roll, and yaw), heading reference and the like which are dependent on the precision of the sensors' outputs. For example, when integration of raw data output by the sensor is used to determine velocity from acceleration or orientation angle from the rate of angular change, the bias drift problem may be significantly magnified.

In light of these characteristics of MEMS sensors, it may be desirable to perform a sensor calibration operation to characterize the bias or sensitivity error, enabling a correction of the sensor data. A sensor calibration operation may employ mathematical calculations to deduce various motion states and the position or orientation of a physical system. A sensor bias may be produced by the calibration operation, which may then be applied to the raw sensor data and calibrate the sensor. As will be appreciated, the calibration operation may be performed during manufacture or may be performed periodically while the device is being used to account for changes that may occur over time. Although performing a calibration operation may be used to improve the quality of data obtained from the sensor, it nevertheless requires power, processing time and other resources and may also disrupt usage of the sensor. Thus, it may not be feasible to continuously calibrate the sensor. Further, the frequency at which the calibration is performed should be balanced against the consumption of resources. Accordingly, this disclosure is directed to systems and methods for performing a calibration operation for a sensor at an advantageous time. While the following discussion is in the context of MEMS sensors as used in portable devices, one of skill in the art will recognize that these techniques may be employed to any suitable sensor application as desired.

### SUMMARY

This disclosure is directed to a device that includes at least one sensor, a system monitor configured to obtain a condition of the device, and a calibration scheduler configured to initiate a calibration operation for the at least one sensor based, at least in part, on the condition of the device obtained from the system monitor. In one aspect, the condition may be one of a motion state, a charging state, a pattern of motion, an orientation, a location, a surrounding environment measurement, sensor usage, an age of calibration and a quality of calibration. Further, the at least one sensor may be an accelerometer, a gyroscope, a magnetometer or a pressure sensor.

In one aspect, the at least one sensor may be a pressure sensor and the calibration operation may involve external data correlated with a determined location of the device.

In another aspect, the system monitor may be configured to determine when the device is charging and the calibration operation may be performed for a motionless device.

In yet another aspect, the calibration operation may be performed a plurality of times at different temperatures to determine an effect of temperature on the at least one sensor.

Further, the system monitor and calibration scheduler are configured to cycle between an active state and an inactive state.

In one embodiment, the condition may be usage of the at least one sensor.

Also, the condition of the device may be a defined orientation or a pattern of motion and the calibration operation may be a factory calibration.

The device may include an application processor and a sensor processor, such that the system monitor and the calibration scheduler are implemented using the sensor processor without requiring involvement of the application processor.

As desired, the system monitor and the calibration scheduler may be implemented using a processor located on the device, using a processor located external to the device, or both.

In one aspect, the system monitor may obtain the condition of the device based, at least in part, on output from the at least one sensor.

In another aspect, the condition may include linear acceleration and the calibration operation may be performed for a gyroscope or an accelerometer.

This disclosure also includes methods for calibrating a sensor. In one aspect, the method may involve obtaining a condition of a device incorporating the sensor and initiating a calibration operation for the sensor based, at least in part, on the condition of the device. The condition may be a motion state, a charging state, a pattern of motion, an orientation, a location, a surrounding environment measurement, sensor usage, an age of calibration or a quality of calibration. Further, the at least one sensor may be an accelerometer, a gyroscope, a magnetometer or a pressure sensor.

Additionally, this disclosure also includes a non-transitory processor-readable storage medium for calibrating a sensor incorporated into a device, the processor-readable storage medium having instructions thereon, when executed by a processor to cause the device to obtain a condition of the device and perform a calibration operation for the sensor based, at least in part, on the condition of the device. The condition may be a motion state, a charging state, a pattern of motion, an orientation, a location, a surrounding environment measurement, sensor usage, an age of calibration or a quality of calibration. Still further, the at least one sensor may be an accelerometer, a gyroscope, a magnetometer or a pressure sensor.

### BRIEF DESCRIPTION OF THE DRAWINGS

FIG. 1 is a block diagram of a system that utilizes a calibration scheduler in accordance with an embodiment.

FIG. 1a is a block diagram of a system that utilizes a calibration scheduler in accordance with an embodiment.

FIG. 2 depicts a flow chart representing the scheduling of a calibration operation in accordance with an embodiment.

### DETAILED DESCRIPTION

At the outset, it is to be understood that this disclosure is not limited to particularly exemplified materials, architectures, routines, methods or structures as such may vary. Thus, although a number of such options, similar or equivalent to those described herein, can be used in the practice or embodiments of this disclosure, the preferred materials and methods are described herein.

It is also to be understood that the terminology used herein is for the purpose of describing particular embodiments of this disclosure only and is not intended to be limiting.

The detailed description set forth below in connection with the appended drawings is intended as a description of exemplary embodiments of the present disclosure and is not intended to represent the only exemplary embodiments in which the present disclosure can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the specification. It will be apparent to those skilled in the art that the exemplary embodiments of the specification may be practiced without these specific details. In some instances, well known structures and devices are shown in block diagram form in order to avoid obscuring the novelty of the exemplary embodiments presented herein.

For purposes of convenience and clarity only, directional terms, such as top, bottom, left, right, up, down, over, above, below, beneath, rear, back, and front, may be used with respect to the accompanying drawings or chip embodiments. These and similar directional terms should not be construed to limit the scope of the disclosure in any manner.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the exemplary wireless communications devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, performs one or more of the methods described above. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor. For example, a carrier wave may be employed to carry computer-readable electronic data such as those used in transmitting and receiving electronic mail or in accessing a network such as the Internet or a local area network (LAN). Of course, many modifications may be made to this configuration without departing from the scope or spirit of the claimed subject matter.

The various illustrative logical blocks, modules, circuits and instructions described in connection with the embodiments disclosed herein may be executed by one or more processors, such as one or more digital signal processors (DSPs), general purpose microprocessors, application specific integrated circuits (ASICs), application specific instruction set processors (ASIPs), field programmable gate arrays (FPGAs), or other equivalent integrated or discrete logic circuitry. The term “processor,” as used herein may refer to any of the foregoing structure or any other structure suitable for implementation of the techniques described herein. In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

Unless defined otherwise, all technical and scientific terms used herein have the same meaning as commonly understood by one having ordinary skill in the art to which the disclosure pertains.

Finally, as used in this specification and the appended claims, the singular forms “a, “an” and “the” include plural referents unless the content clearly dictates otherwise.

This disclosure generally relates to the calibration of sensors and more specifically to initiating the calibration of a sensor at one or more advantageous times. To that end, the following description is provided to enable one of ordinary skill in the art to make and use the techniques of this disclosure. Various modifications to the described embodiments and the generic principles and features described herein will be readily apparent to those skilled in the art. Thus, the present disclosure is not intended to be limited to the embodiments shown, but is to be accorded the widest scope consistent with the principles and features described herein.

A system and method in accordance with the described embodiments utilizes information about a condition of device incorporating at least one sensor in order to initiate a calibration operation involving that sensor at an advantageous time. To describe the features of the present invention in more detail refer now to the following description in conjunction with the accompanying Figures.

In the described embodiments, a chip is defined to include at least one substrate typically formed from a semiconductor material. A single chip may be formed from multiple substrates, where the substrates are mechanically bonded to preserve the functionality. Multiple chip includes at least 2 substrates, wherein the 2 substrates are electrically connected, but do not require mechanical bonding. A package provides electrical connection between the bond pads on the chip to a metal lead that can be soldered to a PCB. A package typically comprises a substrate and a cover. Integrated Circuit (IC) substrate may refer to a silicon substrate with electrical circuits, typically CMOS circuits. MEMS substrate provides mechanical support for the MEMS structure. The MEMS structural layer is attached to the MEMS substrate. The MEMS substrate is also referred to as handle substrate or handle wafer. In some embodiments, the handle substrate serves as a cap to the MEMS structure. In the described embodiments, an electronic device incorporating a sensor may employ a motion tracking module also referred to as Motion Processing Unit (MPU) that includes at least one sensor in addition to electronic circuits. The sensor, such as a gyroscope, a compass, a magnetometer, an accelerometer, a microphone, a pressure sensor, a proximity sensor, or an ambient light sensor, among others known in the art, are contemplated. Some embodiments include accelerometer, gyroscope, and magnetometer, which each provide a measurement along three axes that are orthogonal relative to each other referred to as a 9-axis device. Other embodiments may not include all the sensors or may provide measurements along one or more axes. The sensors may be formed on a first substrate. Other embodiments may include solid-state sensors or any other type of sensors. The electronic circuits in the MPU receive measurement outputs from the one or more sensors. In some embodiments, the electronic circuits process the sensor data. The electronic circuits may be implemented on a second silicon substrate. The first substrate may be vertically stacked, attached and electrically connected to the second substrate in a single semiconductor chip.

In one embodiment, the first substrate is attached to the second substrate through wafer bonding, as described in commonly owned U.S. Pat. No. 7,104,129, which is incorporated herein by reference in its entirety, to simultaneously provide electrical connections and hermetically seal the MEMS devices. This fabrication technique advantageously enables technology that allows for the design and manufacture of high performance, multi-axis, inertial sensors in a very small and economical package. Integration at the wafer-level minimizes parasitic capacitances, allowing for improved signal-to-noise relative to a discrete solution. Such integration at the wafer-level also enables the incorporation of a rich feature set which minimizes the need for external amplification.

In the described embodiments, raw data refers to measurement outputs from the sensors which are not yet processed. Motion data refers to processed raw data. Processing may include applying a sensor fusion algorithm or applying any other algorithm. In the case of the sensor fusion algorithm, data from one or more sensors are combined to provide an orientation of the device. In the described embodiments, a MPU may include processors, memory, control logic and sensors among structures.

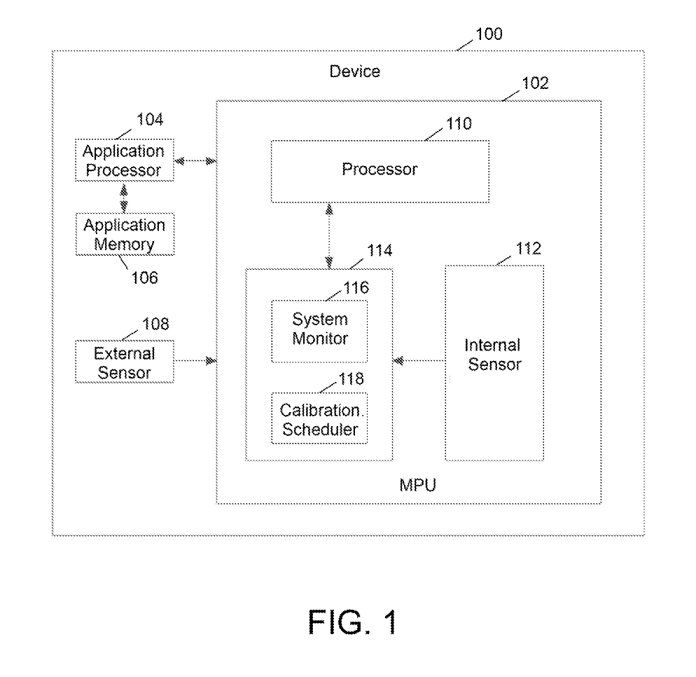

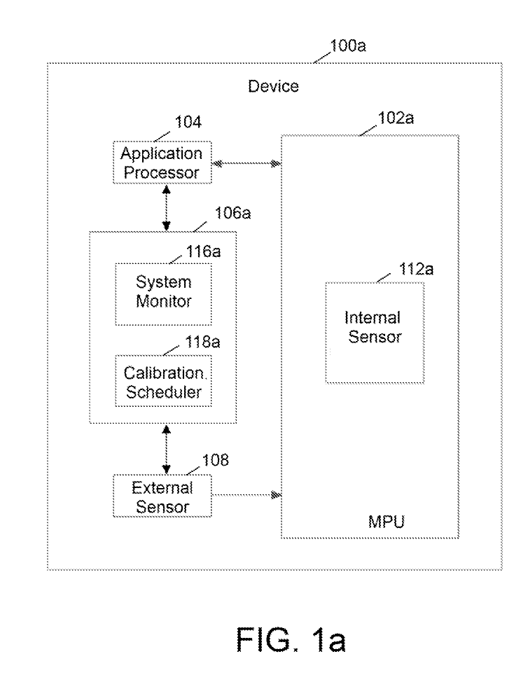

Details regarding one embodiment of an electronic device 100 including features of this disclosure are depicted as high level schematic blocks in FIG. 1. As shown, device 100 includes MPU 102, application processor 104, application memory 106, and external sensor 108. Application processor 104 may be configured to perform the various computations and operations involved with the general function of device 100. Application processor 104 may be coupled to MPU 102 through any suitable bus or interfaces, such as a peripheral component interconnect express (PCIe) bus, a Inter-Integrated Circuit (I2C) bus, a universal serial bus (USB), a universal asynchronous receiver/transmitter (UART) serial bus, a suitable advanced microcontroller bus architecture (AMBA) interface, a serial digital input output (SDIO) bus, or other equivalent. Application memory 106 may include programs, drivers or other data that utilize information provided by MPU 102. In this embodiment, MPU 102 is shown to include sensor processor 110, memory 114 and internal sensor 112. Memory 114 may store algorithms, routines or other instructions for processing data output by sensor 112 or sensor 108 as well as processed data from processor 110 or application processor 104. Internal sensor 112 may include one or more sensors, such as accelerometers, gyroscopes, magnetometers, pressure sensors, humidity sensor, microphones and other sensors. Likewise, external sensor 108 may include one or more sensors, such as accelerometers, gyroscopes, magnetometers, pressure sensors, microphones, proximity, and ambient light sensors, and temperature sensors among others sensors.

In some embodiments, the sensor processor 110 and sensor 112 are formed on different substrates and in other embodiments; they reside on the same substrate. In yet other embodiments, the sensor processor 110 and sensor 112 reside on a same chip or same package. In yet other embodiments, a sensor fusion algorithm that is employed in calculating orientation of device is performed externally to the sensor processor 110 and MPU 102, such as by application processor 104. In still other embodiments, the sensor fusion is performed by MPU 110 or while on other embodiments, a portion of the sensor fusion algorithm is performed in the sensor processor 110 and another portion in MPU 110.

FIG. 1a. As shown, device 100a includes MPU 102a, application processor 104, application memory 106a, and external sensor 108. Application processor 104 may be configured to perform the various computations and operations involved with the general function of device 100a. MPU 102a includes internal sensor 112a. Application memory 106a may include programs, drivers or other data that utilize information provided by MPU 102a. As depicted, system monitor 116a and calibration scheduler 118a may be implemented as a set of instructions stored in memory 106a to be executed by application processor 104. In an embodiment, application processor 104 executes code, according to the algorithms, routines or other instructions in application memory 106a, to process sensor data from internal sensor 112a, as well as external sensors 108a. In some embodiments sensor 112 is similar to sensor 112a, and application memory 106 is similar to application memory 106a except for the location on the device. In many of the embodiments, references to system monitor 116 apply to system monitor 116a, similarly references to calibration scheduler 118 apply to calibration scheduler 118a.

In an embodiment, one or more system generated notifications or events may be controlled using information about device condition obtained from system monitor 116. For example, notifications and the like may be turned off when the device is charging. Accordingly, the decision to turn-off notifications may be based on context, motion of the device, charging, time of the day, input from a sensor such as a light sensor, or the like. In an embodiment, inputs to decide to turn-off notifications or otherwise control events may be made by users. The notifications may be divided into all emails, selected emails by subject, sender or the like, phone calls on your contact list, all phone calls, app notifications, social media notifications, and other similar events. There may also be an option for turning off options when it is dark and charging and/or dependent upon time by using appropriate sensor inputs.

In an embodiment, the sensor processor 110 executes code, according to the algorithms, routines or other instructions in memory 114, to process sensor data. In another embodiment, the application processor 104 sends to or retrieves from application memory 106 and is coupled to the sensor processor 110. Sensor processor 110 may then execute the instructions in memory 114 in accordance with the application in the application processor 102. Examples of applications include a navigation system, compass accuracy, remote control, 3-dimensional camera, gesture recognition or any other motion tracking application. It is understood that this is not an exhaustive list of applications and that others are contemplated.

A bias error or sensitivity error may be estimated using a calibration operation with respect to either or both internal sensor 114 and external sensor 108. The calibration operation may be performed using sensor processor 110, application processor 104, an external processor, or any combination thereof. Similarly, instructions related to the calibration operation may be stored in any combination of memory 112, memory 106 or external memory.

As will be discussed in detail, the techniques of this disclosure involve initiating the calibration operation in response to information regarding a condition of device 100. In the embodiment shown in FIG. 1, system monitor 116 may be configured to gather information regarding a condition of device 100 from any available source, including sensor processor 110, internal sensor 114, external sensor 108 and/or application processor 104. Based at least in part on the information, calibration scheduler 118 may then initiate the calibration operation. As depicted, system monitor 116 and calibration scheduler 118 may be implemented as a set of instructions stored in memory 114 to be executed by sensor processor 110. In other embodiments, system monitor 116 or calibration scheduler 118 may be implemented in any desired combination of software, firmware and hardware at any suitable location, and may be external to device 100. In one aspect, power efficiencies may be realized if system monitor 116 and calibration scheduler 118 do not require involvement of application processor 104.

In one aspect, the information regarding the condition of device 100 may relate to a physical state of device 100. For example, system monitor 118 may gather information reflecting the motion currently being experienced by device 100. As known to those of skill in the art, certain motion states facilitate the calibration operation. Notably, a calibration involving a gyroscope may be performed advantageously under a motionless condition. Similarly, calibration of an accelerometer or a gyroscope may benefit from being performed when device 100 is experiencing a relatively small amount of linear acceleration. Accordingly, system monitor 116 may gather information indicating the motion state of device 100 and calibration scheduler 118 may initiate a calibration operation in response to the motion state.

System monitor 116 may obtain information indicating the motion state of device 100 directly from the sensor being calibrated or through one or more additional sensors. Further, system monitor 116 may obtain the information by inference. A typical use case is that device 100 will be in a motionless state while it is being charged. Thus, information regarding the charging state of device 100 may be obtained from application processor 104. For example, in the Android™ operating system, the charging state may be read from the hardware abstraction layer. Other operating systems may allow information regarding charging state to be obtained in an analogous manner in other operating systems. In another embodiment, noise in magnetometer data may be monitored to determine whether charging is occurring and whether device 100 is being used.

In another aspect, the information regarding the condition of device 100 may involve recognizing a defined orientation or pattern of motion. As noted above, a factory calibration operation may be performed as part of the manufacturing process and it may be desirable to initiate the operation at a specific time. Accordingly, the defined orientation or pattern of motion may be established based on the manufacturing process or the process may be modified to include a defined orientation or pattern of motion. System monitor 116 may then use the defined orientation or pattern of motion to identify the desired time for calibration, such that calibration scheduler 118 may initiate the calibration operation.

In yet another aspect, the condition of device 100 may be correlated with the availability of external information that may be used to facilitate the calibration operation. For example, system monitor 116 may determine the geographic location of device, such as by using global positioning system techniques, wireless communication signal ranging or any other suitable method. Correspondingly, calibration scheduler 118 may initiate a calibration operation for a pressure sensor when pressure data for that location is available. Pressure data may be obtained from an external source, such as the Internet.

Still further, the condition of device 100 as determined by system monitor 116 may include assessing the calibration state of one or more sensors. In one aspect, this may include determining the amount of time that has elapsed since the last calibration operation. As noted above, the bias of a sensor may vary over time. As such, if a calibration operation has not been performed within a designated period of time, calibration scheduler 118 may determine that sufficient drift has likely occurred and correspondingly initiate a calibration routine. Alternatively, if system monitor 116 determines that a calibration operation has been performed sufficiently recently, calibration scheduler 118 may defer initiating a calibration operation to conserve power and other resources. For example, even if the device is currently charging, it may be desirable to avoid unnecessary calibration operations to allow the device charging to finish more quickly. Furthermore, if the device is connected to a power source but the battery is fully charged, the calibration scheduler may elect to perform calibration operations.

In addition, it may be desirable to periodically perform calibration operations in order to determine variations in bias and/or sensitivity over time. In one example, this may be used to help correlate sensor errors with temperature and may allow future compensations to be implemented based on measured temperature as an alternative or in addition to calibration operations.

Further, the calibration state may include an assessment of the quality of the current calibration. Any suitable metric may be applied to assess the calibration quality, including agreement with one or more additional sensors, analysis of the data being output by the sensor and others.

Yet another aspect includes system monitor 116 determining whether a sensor is currently being used, such as from application sensor processor 110. The calibration operation may interfere with current use of the sensor or may create an inconsistencies in the data output if a new offset were applied midstream. Accordingly, it may be advantageous to wait until the sensor is not being used before calibration scheduler 118 initiates the calibration operation.

As desired, calibration scheduler 118 may employ combinations of information regarding the condition of device 100 when determining whether to initiate a calibration operation. For example, information from a plurality of sensors may be used to determine the motion state of device 100. Another suitable combination includes the determination that device 100 is experiencing a relatively small amount of motion together with a determination that there is interference in the magnetometer sensor, the interference in the magnetometer data may indicate the device is in a charging state and it may be advantageous to calibrate one or more sensors.

In conjunction with the above discussions regarding calibration scheduler 118 using information regarding the condition of device 100 as obtained by system monitor 116 to initiate a calibration operation, it may be desirable to operate system monitor 116, calibration scheduler 118, as well as other components related to the calibration operations, by periodically transitioning between an active state and an inactive state, such as in a duty cycle. As discussed above, performing calibration operations represents a consumption of power and other resources. In the context of a portable device that may be powered by a battery, power efficiency is an important design consideration and it may be advantageous to only activate the calibration system, including at least system monitor 116 and calibration scheduler 118, periodically. Even if device 100 is not battery powered or is currently charging, it remains desirable to limit unnecessary consumption of power and other resources.

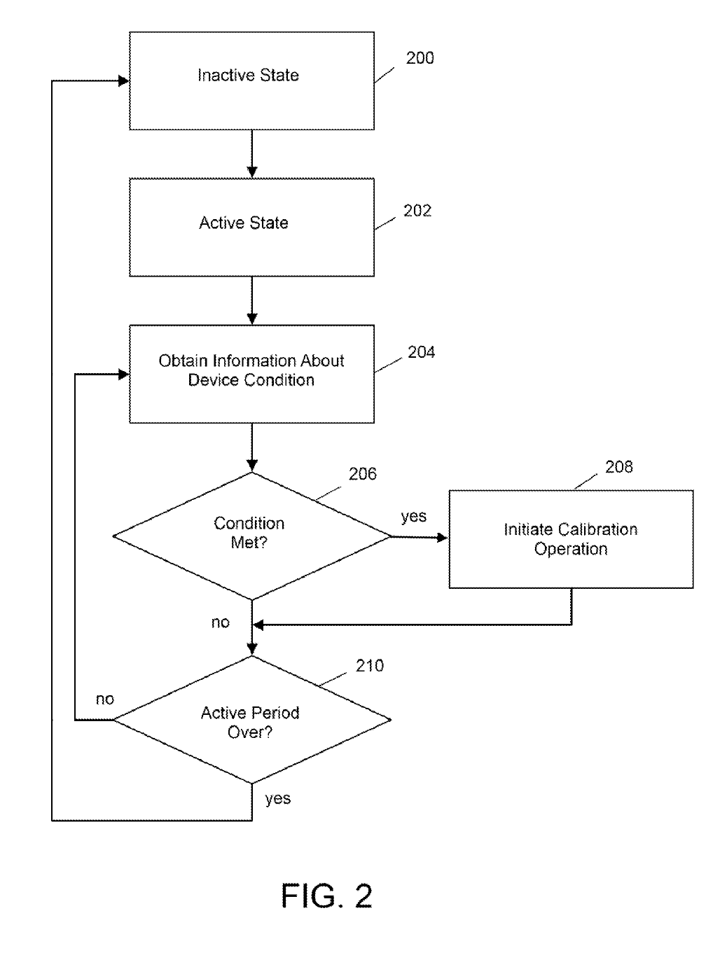

To help illustrate use of a duty cycle, relevant operations of system monitor 116 and calibration scheduler 118 are represented by the flow chart depicted in FIG. 2. Beginning with 200, system monitor 116 and calibration scheduler 118 may be in an inactive state for a period of time corresponding to the particular duty cycle being employed. According to the duty cycle pattern, system monitor 116 and calibration scheduler 118 may then transition to an active state as indicated by 202. In 204, system monitor 116 may obtain information regarding a condition of device 100. As discussed above, the condition of device 100 may include information about a physical state of device 100, such as a motion state, a charging state, a pattern of motion, an orientation, a location, or the like, about its surrounding environment, about sensor usage or about its calibration state, such as quality or age of calibration. In 206, calibration scheduler 118 may determine whether the condition of the device meets one or more thresholds or criteria. If calibration scheduler 118 determines a calibration operation may be performed advantageously based, at least in part, on the information about the condition of device 100, the routine may flow to 208 and calibration scheduler 118 may initiate a calibration operation for at least one sensor, such as internal sensor 114 or external sensor 108, and the routine then progresses to 210. If the determined condition is not sufficient, the routine flows directly to 210. In 210, if the active period set by the duty cycle has expired, the routine return to 200 with system monitor 116 and calibration scheduler 118 transitioning to the inactive state. If the active period has not expired, the routine instead returns to 204 and system monitor 116 may continue to obtain information about the condition of device 100.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. A device comprising:
at least one sensor;
a system monitor configured to obtain a condition of the device; and
a calibration scheduler configured to initiate a calibration operation for the at least one sensor based, at least in part, on the condition of the device obtained from the system monitor.

2. The device of claim 1, wherein the condition is at least one of a motion state, a charging state, a pattern of motion, an orientation, a location, a surrounding environment measurement, sensor usage, an age of calibration and a quality of calibration.

3. The device of claim 1, wherein the at least one sensor is one of an accelerometer, a gyroscope, a magnetometer and a pressure sensor.

4. The device of claim 3, wherein the at least one sensor is a pressure sensor and the calibration operation involves external data correlated with a determined location of the device.

5. The device of claim 1, wherein the system monitor is configured to determine when the device is charging and wherein the calibration operation is performed for a motionless device.

6. The device of claim 1, wherein the calibration operation is performed a plurality of times at different temperatures to determine an effect of temperature on the at least one sensor.

7. The device of claim 1, wherein the system monitor and calibration scheduler are configured to cycle between an active state and an inactive state.

8. The device of claim 1, wherein the condition comprises usage of the at least one sensor.

9. The device of claim 1, wherein the condition of the device comprises a defined orientation and wherein the calibration operation is a factory calibration.

10. The device of claim 1, wherein the condition of the device comprises a defined pattern of motion and wherein the calibration operation is a factory calibration.

11. The device of claim 1, wherein the device further comprises an application processor and a sensor processor, wherein the system monitor and the calibration scheduler are implemented using the sensor processor without requiring involvement of the application processor.

12. The device of claim 1, wherein the system monitor and the calibration scheduler are implemented using a processor located on the device.

13. The device of claim 1, wherein the system monitor and the calibration scheduler are implemented using a processor located external to the device.

14. The device of claim 1, wherein the system monitor and the calibration scheduler are partially implemented using a first processor located on the device and partially implemented using a second processor located external to the device.

15. The device of claim 1, wherein the system monitor obtains the condition of the device based, at least in part, on output from the at least one sensor.

16. The device of claim 1, wherein the condition includes linear acceleration and wherein the calibration operation is performed for at least one of a gyroscope and an accelerometer.

17. A method for calibrating a sensor, comprising:
obtaining a condition of a device incorporating the sensor; and
initiating a calibration operation for the sensor based, at least in part, on the condition of the device.

18. The method of claim 17, wherein the condition is at least one of a motion state, a charging state, a pattern of motion, an orientation, a location, a surrounding environment measurement, sensor usage, an age of calibration and a quality of calibration.

19. The method of claim 17, wherein the at least one sensor is one of an accelerometer, a gyroscope, a magnetometer and a pressure sensor.

20. The method of claim 19, wherein the at least one sensor is a pressure sensor and the calibration operation involves external data correlated with a determined location of the device.

21. The method of claim 17, wherein the condition is the device being in a charging state and the calibration operation is performed for a motionless device.

22. The method of claim 17, wherein the calibration operation is performed a plurality of times at different temperatures to determine an effect of temperature on the at least one sensor.

23. The method of claim 17, further comprising cycling a calibration system for obtaining the condition of the device and initiating the calibration operation between an active state and an inactive state.

24. The method of claim 17, wherein the condition comprises usage of the at least one sensor.

25. The method of claim 17, wherein the condition of the device comprises a defined orientation and wherein the calibration operation is a factory calibration.

26. The method of claim 17, wherein the condition of the device comprises a defined pattern of motion and wherein the calibration operation is a factory calibration.

27. The method of claim 17, wherein the condition of the device is obtained based, at least in part, on output from the at least one sensor.

28. The method of claim 17, wherein the condition includes linear acceleration and wherein the calibration operation is performed for at least one of a gyroscope and an accelerometer.

29. A non-transitory processor-readable storage medium for calibrating a sensor incorporated into a device, the processor-readable storage medium having instructions thereon, when executed by a processor to cause the device to:
obtain a condition of the device; and
perform a calibration operation for the sensor based, at least in part, on the condition of the device.

30. The storage medium of claim 29, wherein the condition is at least one of a motion state, a charging state, a pattern of motion, an orientation, a location, a surrounding environment measurement, sensor usage, an age of calibration and a quality of calibration.

31. The storage medium of claim 29, wherein the condition is the device being in a charging state and the calibration operation is performed for a motionless device.

32. The storage medium of claim 29, wherein the calibration operation is performed a plurality of times at different temperatures to determine an effect of temperature on the at least one sensor.

33. The storage medium of claim 29, further comprising instructions for cycling a calibration system for obtaining the condition of the device and initiating the calibration operation between an active state and an inactive state.

34. The storage medium of claim 29, wherein the condition comprises usage of the at least one sensor.

35. The storage medium of claim 29, wherein the condition of the device comprises a defined orientation and wherein the calibration operation is a factory calibration.

36. The storage medium of claim 29, wherein the condition of the device comprises a defined pattern of motion and wherein the calibration operation is a factory calibration.

37. The storage medium of claim 29, wherein the condition of the device is obtained based, at least in part, on output from the at least one sensor.

38. The storage medium of claim 29, wherein the condition includes linear acceleration and wherein the calibration operation is performed for at least one of a gyroscope and an accelerometer.
